(19) United States
(12) Patent Application Publication
(10) Pub. No.: US 2025/0157906 A1
(43) Pub. Date: May 15, 2025

(54) FABRICATING SEMICONDUCTOR STRUCTURES FOR SEMICONDUCTOR PACKAGING

(71) Applicant: Yangtze Memory Technologies Co., Ltd., Wuhan (CN)

(72) Inventors: Hao ZHENG, Wuhan (CN); Dongyu FAN, Wuhan (CN); Tingting GAO, Wuhan (CN); Lei LIU, Wuhan (CN); Wenxi ZHOU, Wuhan (CN); Zhiliang XIA, Wuhan (CN)

(21) Appl. No.: 18/399,626

(22) Filed: Dec. 28, 2023

(30) Foreign Application Priority Data
Nov. 14, 2023 (CN) 202311530822.6

(51) Int. Cl. H01L 23/498; H01L 21/48; H01L 23/538; H10B 80/00

(52) U.S. Cl. CPC H01L 23/49838; H01L 21/4857; H01L 23/49822; H01L 23/5383; H01L 23/5386; H10B 80/00

(57) ABSTRACT

Systems, devices, and methods for fabricating semiconductor structures for semiconductor packaging are provided. One example method includes forming a stack of conductive layers interleaved with isolating layers in a redistribution layer (RDL) structure of a semiconductor device. First contact structures and second contact structures are formed in the RDL structure, where each of the first contact structures extends through a portion of the conductive layers and the isolating layers and is connected to a pad on a first interface of the RDL structure, each of the second contact structures is connected to a respective one of the first contact structures through one of the conductive layers, and each of the second contact structures is connected to a pad on a second interface of the RDL structure opposite to the first interface.

### CROSS-REFERENCE TO RELATED APPLICATIONS

This application claims priority to Chinese Patent Application No. 202311530822.6, filed on Nov. 14, 2023, which is hereby incorporated by reference in its entirety.

### TECHNICAL FIELD

The present disclosure relates to semiconductor devices and fabrication processes for semiconductor devices.

### BACKGROUND

Semiconductor devices can have various structures to facilitate semiconductor packaging process. A redistribution layer (RDL) on a semiconductor chip can reorganize the electrical connections to the semiconductor chip. When an integrated circuit is manufactured, it usually has a set of I/O pads that are wire-bonded to the pins of the package. A RDL is an extra layer of wiring on the chip that can enable bond out from different locations on the chip, making chip-to-chip bonding simpler. The RDL can also be used for spreading the contact points around a die, so that solder balls can be applied, and the thermal stress of mounting can be spread.

In highly integrated semiconductor packaging, such as the heterogeneous integration, numerous chips are stacked through both horizontal and vertical directions. The horizontal and vertical stacking of chips often uses RDL interconnect layers to redistribute chip signal lead-out positions. Therefore, reducing the cost and improving efficiency of RDL fabrication are often desired.

### SUMMARY

The present disclosure describes methods, devices, systems and techniques for fabricating semiconductor structures for semiconductor packaging.

Certain aspects of the subject matter described here can be implemented as a semiconductor device. The semiconductor device includes a chip and a RDL structure disposed on the chip. The RDL structure includes a stack of conductive layers interleaved with isolating layers, first pads located on a first interface of the RDL structure, second pads located on a second interface of the RDL structure opposite to the first interface, a first connection region including first contact structures, where each of the first contact structures extends through a portion of the conductive layers and the isolating layers, and each of the first contact structures is connected to one of the first pads, and a second connection region including second contact structures, where each of the second contact structures is connected to a respective one of the first contact structures through one of the conductive layers, and each of the second contact structures is connected to one of the second pads.

The semiconductor device can include one or more of the following features.

In some implementations, a contact structure of the second contact structures includes a first end and a second end opposite to the first end, the second end is connected to one of the second pads, and a size of the first end is larger than a size of the second end.

In some implementations, a contact structure of the first contact structures includes a first end and a second end opposite to the first end, the first end is connected to one of the first pads, and a size of the first end is same as a size of the second end.

In some implementations, each of the first contact structures includes a first conductive material, and each of the second contact structures includes a second conductive material.

In some implementations, the RDL structure includes a slit separating a pair of neighboring contact structures of the first contact structures and separating a pair of neighboring contact structures of the second contact structures, and a contact structure of the first contact structures and a contact structure of the second contact structures are on a same side of the slit and are connected through one of the conductive layers.

In some implementations, a pair of neighboring contact structures of the first contact structures connected to a same conductive layer of the conductive layers are isolated by a first slit in the RDL structure, and a pair of neighboring contact structures of the second contact structures connected to a same conductive layer of the conductive layers are isolated by a second slit in the RDL structure.

In some implementations, the first slit is the same as the second slit.

Certain aspects of the subject matter described here can be implemented as a semiconductor package structure. The semiconductor package structure includes a first chip, a second chip, and a RDL structure disposed on the second chip and connected to the first chip, where the first chip and the second chip are on opposite sides of the RDL structure, and the RDL structure includes a stack of conductive layers interleaved with isolating layers, first pads located on a first interface of the RDL structure, second pads located on a second interface of the RDL structure opposite to the first interface, and the RDL structure connects to the first chip through the first pads and to the second chip through the second pads, a first connection region including first contact structures, where each of the first contact structures extends through a portion of the conductive layers and the isolating layers, and each of the first contact structures is connected to one of the first pads, and a second connection region including second contact structures, where each of the second contact structures is connected to a respective one of the first contact structures through one of the conductive layers, and each of the second contact structures is connected to one of the second pads.

The semiconductor package structure can include one or more of the following features.

In some implementations, each of the first pads is connected to the first chip through a micro bump or a hybrid bonding structure.

In some implementations, a contact structure of the second contact structures includes a first end and a second end opposite to the first end, the second end is connected to one of the second pads, and a size of the first end is larger than a size of the second end.

In some implementations, a contact structure of the first contact structures includes a first end and a second end opposite to the first end, the first end is connected to one of the first pads, and a size of the first end is the same as a size of the second end.

In some implementations, each of the first contact structures includes a first conductive material, and each of the second contact structures includes a second conductive material.

In some implementations, the RDL structure includes a slit separating a pair of neighboring contact structures of the first contact structures, the slit separates a pair of neighboring contact structures of the second contact structures, and a contact structure of the first contact structures and a contact structure of the second contact structures are on a same side of the slit and are connected through one of the conductive layers.

In some implementations, a pair of neighboring contact structures of the first contact structures connected to a same conductive layer of the conductive layers are isolated by a first slit in the RDL structure, and a pair of neighboring contact structures of the second contact structures connected to a same conductive layer of the conductive layers are isolated by a second slit in the RDL structure.

In some implementations, the first slit is the same as the second slit.

Certain aspects of the subject matter described here can be implemented as a method. The method includes forming a stack of conductive layers interleaved with isolating layers in a RDL structure of a semiconductor device. First contact structures and second contact structures are formed in the RDL structure, where each of the first contact structures extends through a portion of the conductive layers and the isolating layers and is connected to a pad on a first interface of the RDL structure, each of the second contact structures is connected to a respective one of the first contact structures through one of the conductive layers, and each of the second contact structures is connected to a pad on a second interface of the RDL structure opposite to the first interface.

The method can include one or more of the following features.

In some implementations, the method further includes forming a slit in the RDL structure to separate a pair of neighboring contact structures of the first contact structures and to separate a pair of neighboring contact structures of the second contact structures, where a contact structure of the first contact structures and a contact structure of the second contact structures are on a same side of the slit and are connected through one of the conductive layers.

In some implementations, the method further includes filling a first isolating material to the slit, filling a second isolating material in each of the first contact structures to form an isolating layer on an inner surface of each of the first contact structures, and filling a first conductive material in the first contact structures and a second conductive material in the second contact structures.

In some implementations, the method further includes forming, in the second contact structures, a third isolating material over the second conductive material, after filling the second conductive material in the second contact structures.

In some implementations, each of the first contact structures includes a first trench, and each of the second contact structures includes a second trench.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example semiconductor device with a RDL structure disposed on a chip.

FIG. 2A illustrates a cross-sectional view of an example semiconductor package structure.

FIG. 2B illustrates a top view of the example semiconductor package structure.

FIG. 2C illustrates another cross-sectional view of the example semiconductor package structure.

FIGS. 3A-3E illustrate an example process for fabricating the RDL structure in FIG. 1.

FIG. 4 illustrates a cross-sectional view of an example semiconductor package structure that includes micro bump structures for connecting a RDL structure to a chip.

FIG. 5 is a flow chart of an example process of forming a semiconductor structure.

FIG. 6 illustrates a block diagram of an example system having a memory device.

Like reference numbers and designations in the various drawings indicate like elements. It is also to be understood that the various exemplary implementations shown in the figures are merely illustrative representations and are not necessarily drawn to scale.

### DETAILED DESCRIPTION

This specification relates to methods, devices, systems and techniques for fabricating semiconductor structures for semiconductor packaging. Redistribution layer (RDL) is a layer added to an integrated circuit or semiconductor chip to redistribute the electrical connections, which allows the integration of multiple dies into a single package. In some cases, fabricating an RDL structure may involve multiple times of thin film depositions, together with multiple steps of etching and material filling. To simplify RDL fabrication, a stack of conductive layers interleaved with isolating layers can be deposited at one time to form the body of a RDL structure. Multiple contact structures (e.g., trenches) can then be formed in the stack and connected to one another under a specific pattern and through the conductive layers in the stack. As such, these interconnected contact structures can be electrically connected to I/O pads, which can redistribute electrical connections to dies in semiconductor packages.

Implementations of the present disclosure can provide one or more of the following technical advantages. For example, the disclosed RDL fabrication process can reduce the complexity and the cost associated with fabricating RDL and semiconductor packaging process, because the disclosed RDL fabrication process can avoid multiple thin film deposition processes during RDL fabrication, and the processes associated with etching and filling materials during RDL fabrication can also be simplified. Additionally, as the number of interleaving conductive layers and isolating layers in the disclosed RDL structure increases, the cost associated with fabricating RDL can decrease. Furthermore, the disclosed RDL fabrication process can increase the flexibility of adjusting the number of pads that are available for electrical connections to dies.

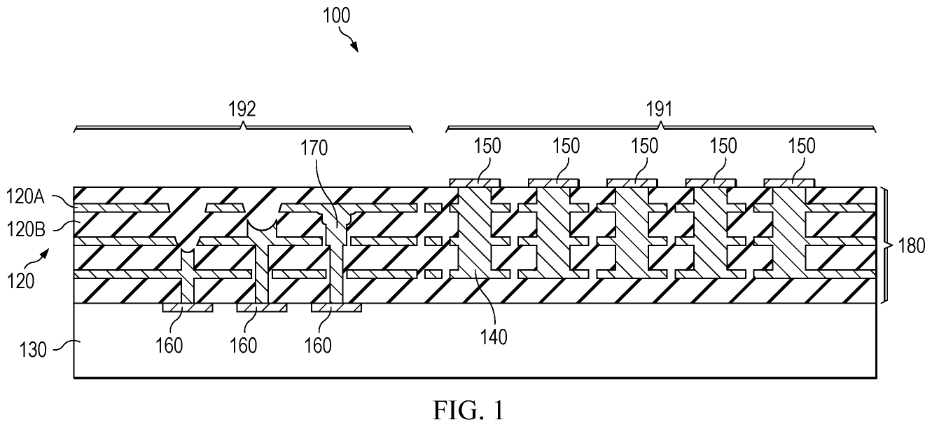

FIG. 1 illustrates a cross-sectional view of an example semiconductor device 100 with a RDL structure 180 disposed on a chip 130. The RDL structure 180 includes a stack 120 of conductive layers 120A interleaved with isolating layers 120B. A first set of pads 150 (e.g., first pads) are located on a first interface of the RDL structure 180. A second set of pads 160 (e.g., second pads) are located on a second interface of the RDL structure opposite to the first interface, and are connected to chip 130. A first connection region 191 includes a first set of contact structures 140 (e.g., first contact structures). Each contact structure in the first set of contact structures 140 extends through a portion of the conductive layers 120A and the isolating layers 120B, and each of the first set of contact structures 140 is connected to a corresponding pad in the first set of pads 150. In some cases, the conductive layer 120A can include a conducting material, for example, copper (Cu). The isolating layers 120B can include a dielectric material, for example, silicon oxide. The first set of pads 150 can include a conducting material, for example, aluminum. The second set of pads 160 can include a conducting material, for example, aluminum. In some cases, the number of conductive layers 120A can be the same as the number of conductive layers 120B, for example, each of 120A and 120B can have three layers respectively. In some cases, the number of conductive layers 120A and the number of conductive layers 120B can also differ by one.

A second connection region 192 includes a second set of contact structures 170 (e.g., second contact structures). Each contact structure in the second set of contact structures 170 is connected to a respective contact structure in the first set of contact structures 140 through one of the conductive layers 120A, and each contact structure in the second set of contact structures 170 is connected to a corresponding pad in the second set of pads 160.

In some implementations, a contact structure in the second set of contact structures 170 includes a first end and a second end opposite to the first end. The second end is electrically connected to a corresponding pad in the second set of pads 160, and a size of the first end is larger than a size of the second end. In some cases, the second set of contact structures 170 can be formed by etching in a direction from the side of RDL structure 180 with the second set of pads 160 to the opposite side of RDL structure 180 with the first set of pads 150.

In some implementations, a contact structure in the first set of contact structures 140 includes a first end and a second end opposite to the first end. The first end is electrically connected to a corresponding pad in the first set of pads 150, and a size of the first end can be larger than a size of the second end. In some cases, the first set of contact structures 140 can be formed by etching in a direction from the side of RDL structure 180 with the first set of pads 150 to the opposite side of RDL structure 180 with the second set of pads 160.

In some implementations, each contact structure in the first set of contact structures 140 includes a first conductive material, and each contact structure in the second set of contact structures 170 includes a second conductive material.

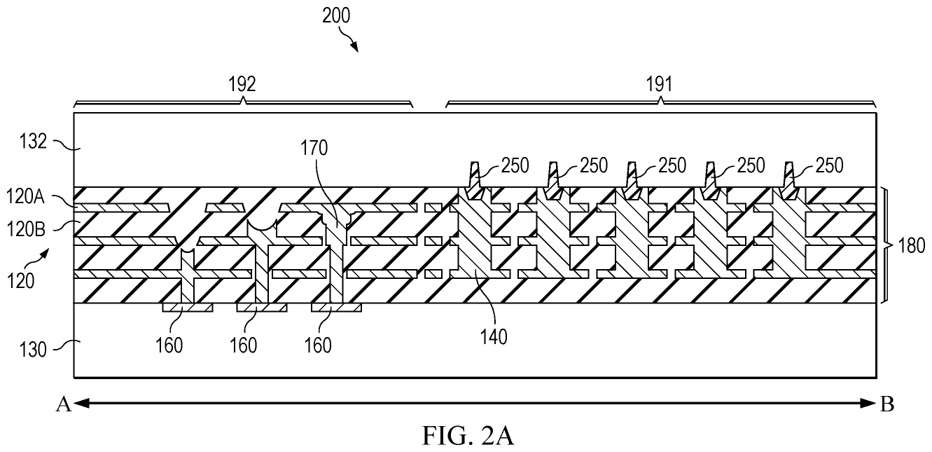

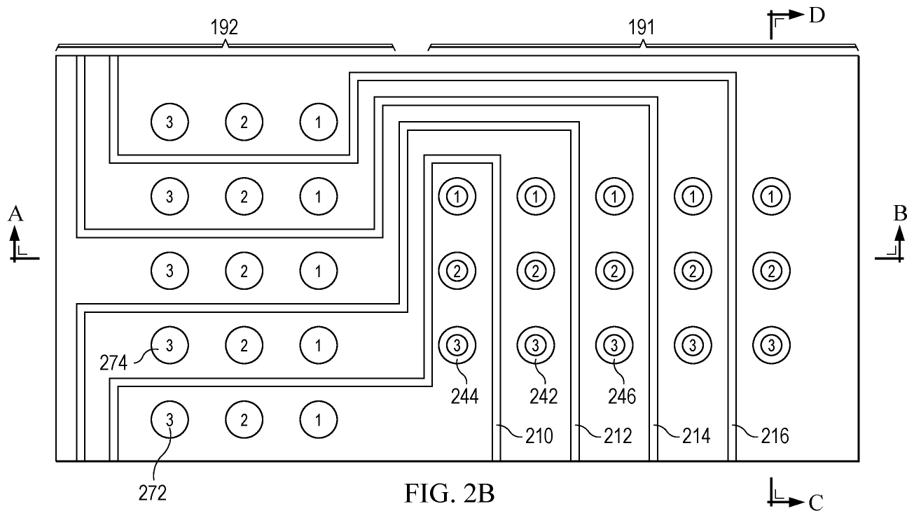

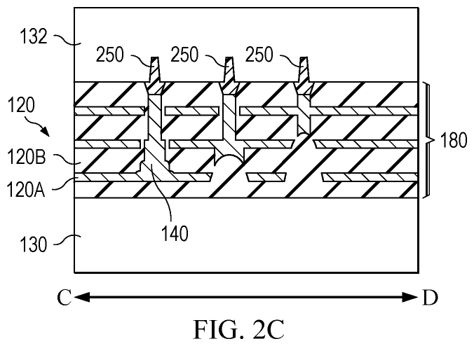

FIG. 2A illustrates a cross-sectional view of an example semiconductor package structure 200 along cut line AB in FIG. 2B. FIG. 2B illustrates a top view of the example semiconductor package structure 200. FIG. 2C illustrates a cross-sectional view of the example semiconductor package structure 200 along cut line CD in FIG. 2B.

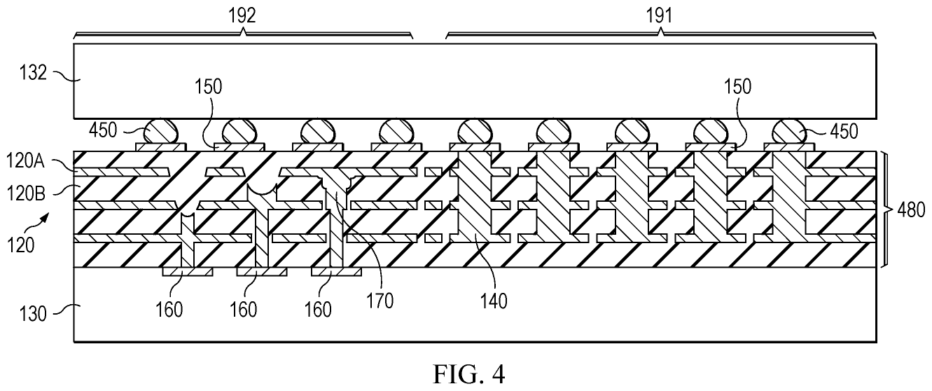

As shown in FIG. 2A, the example semiconductor package structure 200 includes a RDL structure (e.g., RDL structure 180 shown in FIG. 1) and two chips, i.e., Die1 130 (e.g., first chip) and Die2 132 (e.g., second chip). Die1 130 and Die2 132 are connected by RDL structure 180. In the example shown in FIG. 2A, pads 250 used to connect RDL structure 180 to Die2 132 are hybrid bonding structures. In some other examples such as the one shown in FIG. 4, pads 250 can be micro bump pads.

In FIG. 2B, multiple contact structures having the same label, for example, 1, 2, or 3, and in the same connection region (e.g., 191 or 192) can be electrically connected to a same conductive layer of the conductive layers 120A. But if any pair of the multiple contact structures that have the same label and are in the same connection region are separated by a slit, for example, slit 210, 212, 214, or 216, then this pair of contact structures are electrically isolated by the slit. In some cases, each slit in RDL structure 180 can extend through all conductive layers 120A in order to electrically isolate each pair of conduct structures in RDL structure 180 separated by the slit.

In some implementations, RDL structure 180 includes a slit 210 separating a pair of neighboring contact structures in the first set of contact structures 140 (e.g., contact structures 242 and 244). The slit 210 can also separate a pair of neighboring contact structures (e.g., contact structures 272 and 274) in the second set of contact structures 170. In some cases, a contact structure (e.g., contact structure 244) in the first set of contact structures 140 and a contact structure (e.g., contact structure 272) in the second set of contact structures 170 are on the same side of slit 210 and are connected through one of the conductive layers 120A, because both contact structures 244 and 272 are connected to the same conductive layer of the conductive layers 120A.

In some implementations, RDL structure 180 includes more than one slit, for example, slits 210, 212, 214, and 216. Two contact structures (e.g., 242 and 274) that are between two neighboring slits (e.g., slits 210 and 212) can be connected through one of the conductive layers 120A, because both contact structures 242 and 274 are connected to the same conductive layer of the conductive layers 120A.

In some implementations, a pair of neighboring contact structures (e.g., 242 and 246) of the first set of contact structures 140 that are electrically connected to a same conductive layer of the conductive layers 120A, are electrically isolated by a first slit (e.g., 212) in the RDL structure 180. A pair of neighboring contact structures (e.g., 272 and 274) of the second set of contact structures 170 that are electrically connected to a same conductive layer of the conductive layers 120A, are electrically isolated by a second slit (e.g., 210) in the RDL structure 180. In some cases, the first slit can be the same as the second slit. For example, slit 210 can electrically isolate contact structures 242 and 244 in the first set of contact structures 140. Slit 210 can also electrically isolate contact structures 272 and 274 in the second set of contact structures 170.

In some implementations, contact structures in RDL structure 180 and the slits separating the contact structures can be arranged in patterns different than those shown in FIG. 2B, depending on the arrangement of the locations of die pads on Die1 130 and Die2 132 to be connected to pads 160 and 250 respectively. In some cases, in the first connection region 191, each group of three contact structures in FIG. 2B arranged perpendicular to cut line AB, for example, contact structures 246, 247, and 248, can be arranged parallel to cut line AB. Consequently, in the first connection region 191, each slit segment in FIG. 2B arranged perpendicular to cut line AB, for example, the segment of slit 212 separating contact structures 242 and 246, can be arranged parallel to cut line AB. In some cases, each group of three contact structures in FIG. 2B arranged along a side of a slit, for example, contact structures 246, 247, and 248, can be arranged in a reversed order.

In FIG. 2C, three contact structures in the example semiconductor package structure 200 along cut line CD in FIG. 2B are shown. In some cases, the three contact structures can be three contact structures 140 in the first connection region 191 in FIG. 1. As shown in FIG. 2C each of the three contact structures is connected to a corresponding pad 250 that connects RDL structure 180 to Die2 132. Each of the three contact structures is only connected to one corresponding conductive layer, for example, a conductive layer 120A in FIG. 1, such that each of the three contact structures can connect the corresponding pad 250 to another contact structure in the second connection region 192 through the corresponding conductive layer, and therefore connect its corresponding pad 250 to another pad 160 in the second connection region 192. As such, each pad 250 in the first connection region 191 in FIG. 2B can be connected to a pad, for example, pad 160 in FIG. 1, in the second connection region 192 in FIG. 2B.

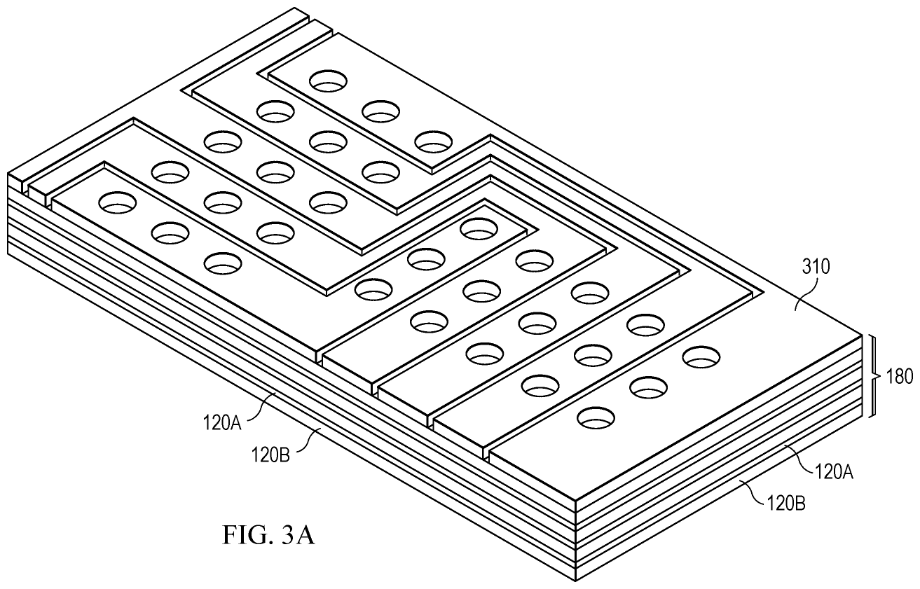

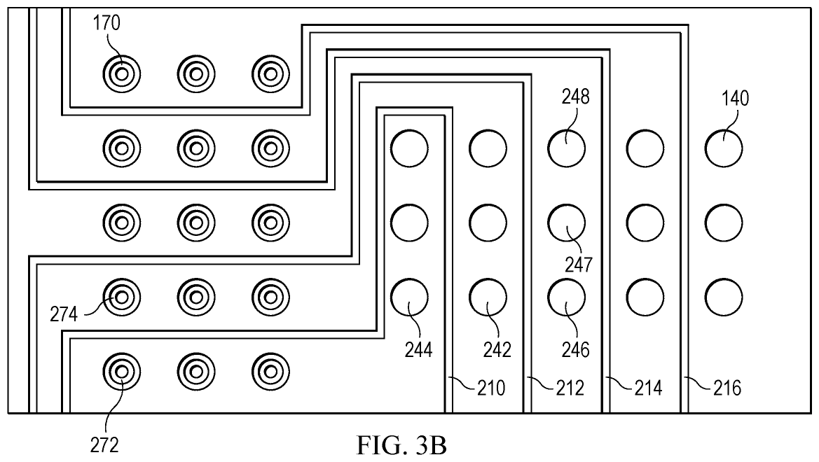

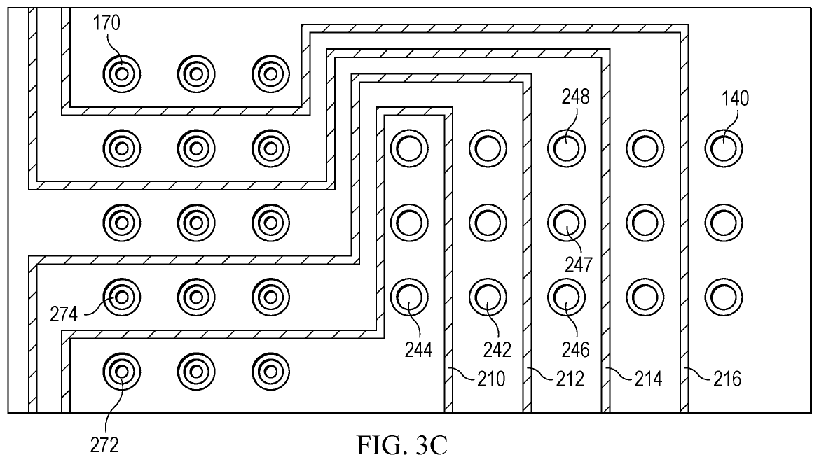

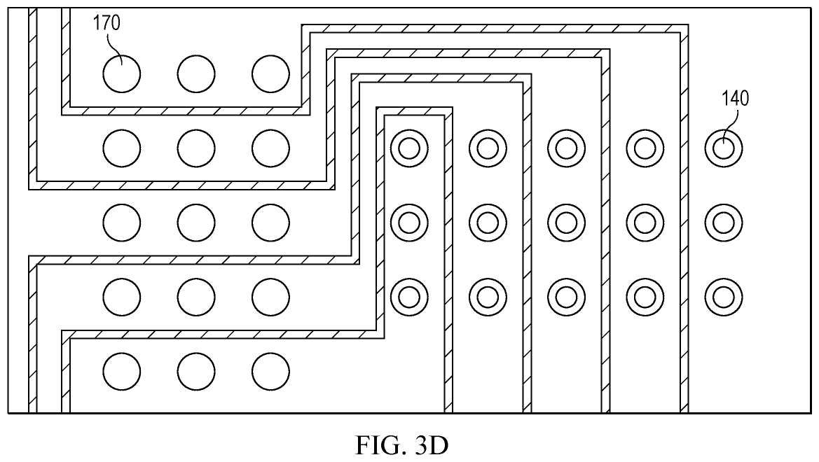

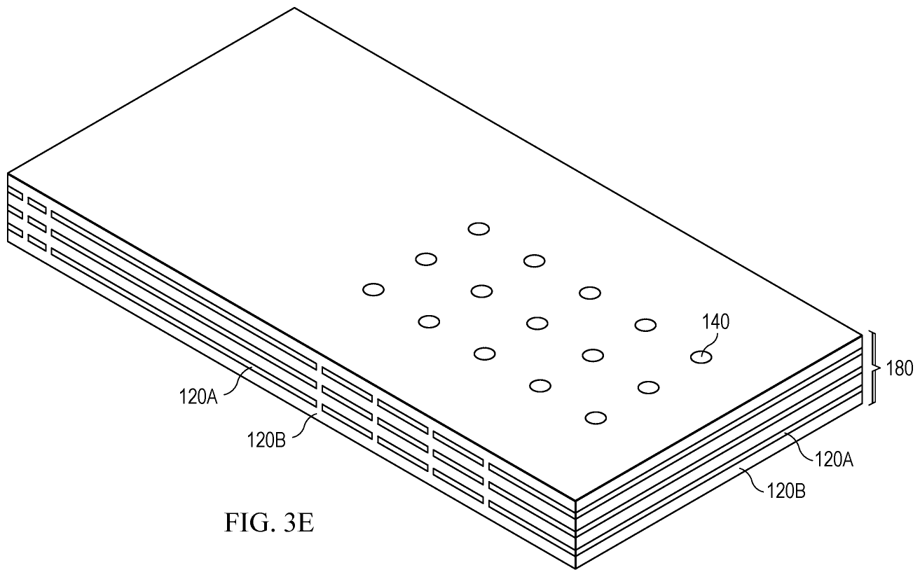

FIGS. 3A to 3E illustrate an example process for fabricating the RDL structure in FIG. 1. As shown in FIG. 3A, the example process includes forming a stack of conductive layers 120A interleaved with isolating layers 120B in a RDL structure 180 of a semiconductor device. In some cases, the conductive layer 120A can include a conducting material, for example, copper (Cu). The isolating layers 120B can include a dielectric material, for example, silicon oxide. The interleaving conductive layers 120A and isolating layers 120B can be formed by depositing one layer above another so as to form the complete stack of conductive layers 120A interleaved with isolating layers 120B, before other structures, for example, contact structures 140 and 170 in FIG. 1, are formed inside the stack of interleaving conductive layers 120A and isolating layers 120B. The number of conductive layers 120A can be the same as the number of conductive layers 120B, for example, each of 120A and 120B can have three layers respectively. The number of conductive layers 120A and the number of conductive layers 120B can also differ by one. In some cases, the example process can also include forming a hard mask 310 over the stack. Hard mask 310 can be used to help forming contact structures 140 and 170 in FIG. 1.

As shown in FIG. 3B, the example process includes forming a first set of contact structures 140 and a second set of contact structures 170 in the RDL structure 180. Each contact structure in the first set of contact structures 140 extends through a portion of the conductive layers 120A and the isolating layers 120B, and each of the first set of contact structures 140 is connected to a corresponding pad on a first interface of the RDL structure 180. Each contact structure in the second set of contact structures 170 is connected to a respective contact structure in the first set of contact structures 140 through one of the conductive layers 120A, and each contact structure in the second set of contact structures 170 is connected to a corresponding pad on a second interface of the RDL structure opposite to the first interface.

In some implementations, each contact structure in the first set of contact structures 140 includes a respective first trench, and each contact structures in the second set of contact structures 170 includes a respective second trench.

In some implementations, the example process can include forming a slit, for example, slit 210, in the RDL structure 180, to separate a pair of neighboring contact structures (e.g., contact structures 242 and 244) in the first set of contact structures 140. Slit 210 also separates a pair of neighboring contact structures (e.g., contact structures 272 and 274) in the second set of contact structures 170. A contact structure (e.g., contact structure 244) in the first set of contact structures 140 and a contact structure (e.g., contact structure 272) in the second set of contact structures 170 are on the same side of slit 210 and are connected through a common conductive layer of the conductive layers 120A.

In some implementations, the example process can include forming more than one slit, for example, slits 210, 212, 214, and 216. Two contact structures (e.g., contact structures 242 and 274) that are between two neighboring slits (e.g., slits 210 and 212) can be connected through a common conductive layer of the conductive layers 120A.

In some implementations, contact structures in RDL structure 180 and the slits separating the contact structures can be arranged in patterns different than those shown in FIG. 3B, depending on the arrangement of the locations of die pads on Die1 130 and Die2 132 to be connected to the contact structure in RDL structure 180. Additional details can be found in the description of FIG. 2B.

As shown in FIG. 3C, the example process includes filling a first isolating material to each of slits 210, 212, 214, and 216, filling a second isolating material in each of the first set of contact structures 140 to form an isolating layer on an inner surface of each of the first set of contact structures 140, and filling the second isolating material in each of the second set of contact structures 170 to form an isolating layer on an inner surface of each of the second set of contact structures 170. Consequently, when each of the first set of contact structures 140 or each of the second set of contact structures 170 extends through one or more conductive layers 120A in RDL structure 180, the isolating layer formed using the second isolating material and on the inner surface of each contact structure in 140 and 170 can isolate each contact structures from the conductive layers 120A that it extends through.

In some implementations, a pair of neighboring contact structures (e.g., contact structures 242 and 246) of the first set of contact structures 140 that are electrically connected to a same conductive layer of the conductive layers 120A, are electrically isolated by a first slit (e.g., slit 212) in the RDL structure 180. A pair of neighboring contact structures (e.g., contact structures 272 and 274) of the second set of contact structures 170 that are electrically connected to a same conductive layer of the conductive layers 120A, are electrically isolated by a second slit (e.g., slit 210) in the RDL structure 180. In some cases, the first slit can be the same as the second slit. For example, slit 210 can electrically isolate contact structures 242 and 244 in the first set of contact structures 140. Slit 210 can also electrically isolate contact structures 272 and 274 in the second set of contact structures 170.

As shown in FIG. 3D, the example process includes filling a second conductive material in the second set of contact structures 170 such that the second conductive material in each of the second set of contact structures 170 can be connected to a corresponding pad, for example, pad 160 that can be connected to Die1 130 in FIG. 2A, and forming, in the second set of contact structures 170, a third isolating material over the second conductive material.

As shown in FIG. 3E, the example process includes filling a first conductive material in the first set of contact structures 140, such that the first conductive material in each of the first set of contact structures 140 can be connected to a corresponding pad, for example, pad 250 that connects to Die2 132 in FIG. 2A, removing the hard mask 310, and obtaining the resulting RDL structure 180. In some cases, the hard mask 310 can be removed using chemical mechanical polishing (CMP). The resulting RDL structure 180 also includes a second side opposite to the side shown in FIG. 3E that exposes the first conductive material in the first set of contact structures 140. The second side exposes the second conductive material in the second set of contact structures 170 that can be connected to pads 160 that can in turn be connected to Die1 130 in FIG. 2A.

FIG. 4 illustrates a cross-sectional view of an example semiconductor package structure that includes micro bump structures for connecting a RDL structure to a chip. In some implementations, the RDL structure 480 in FIG. 4 can be the same as or similar to RDL structure 180 in FIG. 1. As shown in FIG. 4, pads 450 that are used to connect the RDL structure to Die2 have micro bump structures.

In some implementations, to fabricate the example semiconductor package structure in FIG. 4, Die1 130 can be first fabricated. RDL structure 480 can then be formed over Die1 130, with RDL structure 480 connecting to Die1 130 using either hybrid bonding structures shown in pad 250 in FIG. 2A or micro bump structures shown in pad 450 in FIG. 4. After forming RDL structure 480 over Die1 130, Die2 132 can be connected to RDL structure 480 to form the example semiconductor package structure in FIG. 4. RDL structure 480 can then be connected to Die2 132 using either hybrid bonding structures shown in pad 250 in FIG. 2A or micro bump structures shown in pad 450 in FIG. 4.

In some implementations, to fabricate the example semiconductor package structure in FIG. 4, Die2 132 can be first fabricated. RDL structure 480 can then be formed over Die2 132, with RDL structure 480 connecting to Die2 132 using either hybrid bonding structures shown in pad 250 in FIG. 2A or micro bump structures shown in pad 450 in FIG. 4. After forming RDL structure 480 over Die2 132, Die1 130 can be connected to RDL structure 480 to form the example semiconductor package structure in FIG. 4. RDL structure 480 can then be connected to Die1 130 using either hybrid bonding structures shown in pad 250 in FIG. 2A or micro bump structures shown in pad 450 in FIG. 4.

In some implementations, the RDL structure 480 in FIG. 4 includes a stack 120 of conductive layers 120A interleaved with isolating layers 120B. A first set of pads 150 (e.g., first pads) are located on a first interface of the RDL structure 480, and each of the first set of pads 150 is connected to a corresponding pad 450 that in turn connects to Die2 132. A second set of pads 160 (e.g., second pads) are located on a second interface of the RDL structure opposite to the first interface, and are connected to Die1 130. A first connection region 191 includes a first set of contact structures 140 (e.g., first contact structures). Each contact structure in the first set of contact structures 140 extends through a portion of the conductive layers 120A and the isolating layers 120B, and each of the first set of contact structures 140 is connected to a corresponding pad in the first set of pads 150. In some cases, the conductive layer 120A can include a conducting material, for example, copper (Cu). The isolating layers 120B can include a dielectric material, for example, silicon oxide. The first set of pads 150 can include a conducting material, for example, aluminum. The second set of pads 160 can include a conducting material, for example, aluminum. In some cases, the number of conductive layers 120A can be the same as the number of conductive layers 120B, for example, each of 120A and 120B can have three layers respectively. In some cases, the number of conductive layers 120A and the number of conductive layers 120B can also differ by one.

A second connection region 192 includes a second set of contact structures 170 (e.g., second contact structures). Each contact structure in the second set of contact structures 170 is connected to a respective contact structure in the first set of contact structures 140 through one of the conductive layers 120A, and each contact structure in the second set of contact structures 170 is connected to a corresponding pad in the second set of pads 160.

In some implementations, a contact structure in the second set of contact structures 170 includes a first end and a second end opposite to the first end. The second end is electrically connected to a corresponding pad in the second set of pads 160, and a size of the first end is larger than a size of the second end. In some cases, the second set of contact structures 170 can be formed by etching in a direction from the side of RDL structure 480 with the second set of pads 160 to the opposite side of RDL structure 480 with the first set of pads 150.

In some implementations, a contact structure in the first set of contact structures 140 includes a first end and a second end opposite to the first end. The first end is electrically connected to a corresponding pad in the first set of pads 150, and a size of the first end can be larger than a size of the second end. In some cases, the first set of contact structures 140 can be formed by etching in a direction from the side of RDL structure 480 with the first set of pads 150 to the opposite side of RDL structure 480 with the second set of pads 160.

In some implementations, each contact structure in the first set of contact structures 140 includes a first conductive material, and each contact structure in the second set of contact structures 170 includes a second conductive material.

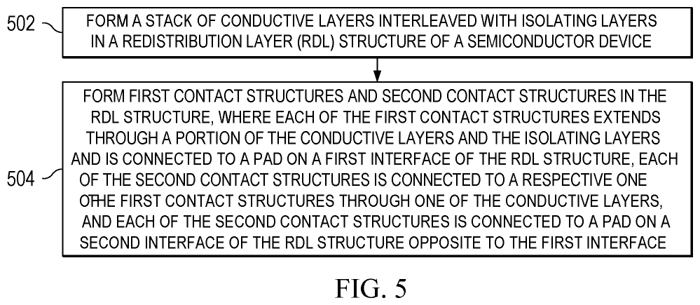

FIG. 5 is a flow chart of an example process of forming a semiconductor structure. The semiconductor structure can be similar to, or same as, the RDL structure 180 of FIG. 1, or a part of the RDL structure 180. The process can be described in view of FIG. 1. The process can include the fabrication process of forming the semiconductor structure in FIGS. 2A-2B or FIGS. 3A-3E. The process includes steps that can be performed with any suitable order and/or any combination.

At 502, the example process includes forming a stack of conductive layers interleaved with isolating layers in a RDL structure of a semiconductor device.

At 504, the example process includes forming first contact structures and second contact structures in the RDL structure. In some implementations, each of the first contact structures extends through a portion of the conductive layers and the isolating layers and is connected to a pad on a first interface of the RDL structure. Each of the second contact structures is connected to a respective one of the first contact structures through one of the conductive layers. Each of the second contact structures is connected to a pad on a second interface of the RDL structure opposite to the first interface.

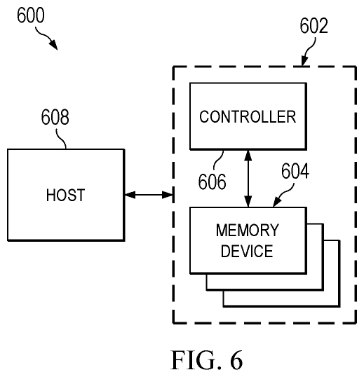

FIG. 6 illustrates a block diagram of an example system 600 having a memory device. System 600 can be a mobile phone, a desktop computer, a laptop computer, a tablet, a vehicle computer, a gaming console, a printer, a positioning device, a wearable electronic device, a smart sensor, a virtual reality (VR) device, an augment reality (AR) device, or any other suitable electronic devices having storage therein. As shown in FIG. 6, system 600 can include a host 608 and a memory system 602 having one or more memory devices 604 and a memory controller 606. Host 608 can be a processor of an electronic device, such as a central processing unit (CPU), or a system-on-chip (SoC), such as an application processor (AP). Host 608 can be configured to send or receive data to or from memory devices 604.

Memory device 604 can be any memory device disclosed in the present disclosure. Memory controller 606 is coupled to memory device 604 and host 608 and is configured to control memory device 604, according to some implementations. Memory controller 606 can manage the data stored in memory device 604 and communicate with host 608. In some implementations, memory controller 606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed for operating in a high duty-cycle environment solid-state drives (SSDs) or embedded multi-media-cards (eMMCs) used as data storage for mobile devices, such as smartphones, tablets, laptop computers, etc., and enterprise storage arrays. Memory controller 606 can be configured to control operations of memory device 604, such as read, erase, and program operations. Memory controller 606 can also be configured to manage various functions with respect to the data stored or to be stored in memory device 604 including, but not limited to bad-block management, garbage collection, logical-to-physical address conversion, wear leveling, etc. In some implementations, memory controller 606 is further configured to process error correction codes (ECCs) with respect to the data read from or written to memory device 604. Any other suitable functions may be performed by memory controller 606 as well, for example, formatting memory device 604.

Memory controller 606 can communicate with an external device (e.g., host 608) according to a particular communication protocol. For example, memory controller 606 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more memory devices 604 can be integrated into various types of storage devices, for example, be included in the same package, such as a universal Flash storage (UFS) package or an eMMC package. That is, memory system 602 can be implemented and packaged into different types of end electronic products. In some implementations, memory system 602 can be implemented and packaged into SSDs such as client SSDs or enterprise SSDs. Client SSDs can be used in electronic devices such as personal computers, digital cameras, smart phones, mobile devices, etc. Enterprise SSDs can be used in enterprise environments such as data centers or servers.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−. 10%, .+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a chip; and
a redistribution layer (RDL) structure disposed on the chip, wherein the RDL structure comprises:
a stack of conductive layers interleaved with isolating layers;
first pads located on a first interface of the RDL structure;
second pads located on a second interface of the RDL structure opposite to the first interface;
a first connection region comprising first contact structures, wherein each of the first contact structures extends through a portion of the conductive layers and the isolating layers, and wherein each of the first contact structures is connected to one of the first pads; and
a second connection region comprising second contact structures, wherein each of the second contact structures is connected to a respective one of the first contact structures through one of the conductive layers, and each of the second contact structures is connected to one of the second pads.

2. The semiconductor device according to claim 1, wherein a contact structure of the second contact structures comprises a first end and a second end opposite to the first end, the second end is connected to one of the second pads, and a size of the first end is larger than a size of the second end.

3. The semiconductor device according to claim 1, wherein a contact structure of the first contact structures comprises a first end and a second end opposite to the first end, the first end is connected to one of the first pads, and a size of the first end is same as a size of the second end.

4. The semiconductor device according to claim 1, wherein each of the first contact structures comprises a first conductive material, and each of the second contact structures comprises a second conductive material.

5. The semiconductor device according to claim 1, wherein the RDL structure comprises a slit separating a pair of neighboring contact structures of the first contact structures and separating a pair of neighboring contact structures of the second contact structures, and a contact structure of the first contact structures and a contact structure of the second contact structures are on a same side of the slit and are connected through one of the conductive layers.

6. The semiconductor device according to claim 1, wherein a pair of neighboring contact structures of the first contact structures connected to a same conductive layer of the conductive layers are isolated by a first slit in the RDL structure, and a pair of neighboring contact structures of the second contact structures connected to a same conductive layer of the conductive layers are isolated by a second slit in the RDL structure.

7. The semiconductor device according to claim 6, wherein the first slit is the same as the second slit.

8. A semiconductor package structure, comprising:
a first chip;
a second chip; and
a redistribution layer (RDL) structure disposed on the second chip and connected to the first chip, wherein the first chip and the second chip are on opposite sides of the RDL structure, and wherein the RDL structure comprises:
a stack of conductive layers interleaved with isolating layers;
first pads located on a first interface of the RDL structure;
second pads located on a second interface of the RDL structure opposite to the first interface, and the RDL structure connects to the first chip through the first pads and to the second chip through the second pads;
a first connection region comprising first contact structures, wherein each of the first contact structures extends through a portion of the conductive layers and the isolating layers, and wherein each of the first contact structures is connected to one of the first pads; and
a second connection region comprising a second contact structures, wherein each of the second contact structures is connected to a respective one of the first contact structures through one of the conductive layers, and each of the second contact structures is connected to one of the second pads.

9. The semiconductor package structure of claim 8, wherein each of the first pads is connected to the first chip through a micro bump or a hybrid bonding structure.

10. The semiconductor package structure of claim 8, wherein a contact structure of the second contact structures comprises a first end and a second end opposite to the first end, the second end is connected to one of the second pads, and a size of the first end is larger than a size of the second end.

11. The semiconductor package structure of claim 8, wherein a contact structure of the first contact structures comprises a first end and a second end opposite to the first end, the first end is connected to one of the first pads, and a size of the first end is the same as a size of the second end.

12. The semiconductor package structure of claim 8, wherein each of the first contact structures comprises a first conductive material, and each of the second contact structures comprises a second conductive material.

13. The semiconductor package structure of claim 8, wherein the RDL structure comprises a slit separating a pair of neighboring contact structures of the first contact structures, the slit separates a pair of neighboring contact structures of the second contact structures, and a contact structure of the first contact structures and a contact structure of the second contact structures are on a same side of the slit and are connected through one of the conductive layers.

14. The semiconductor package structure of claim 8, wherein a pair of neighboring contact structures of the first contact structures connected to a same conductive layer of the conductive layers are isolated by a first slit in the RDL structure, and a pair of neighboring contact structures of the second contact structures connected to a same conductive layer of the conductive layers are isolated by a second slit in the RDL structure.

15. The semiconductor package structure of claim 14, wherein the first slit is the same as the second slit.

16. A method, comprising:
forming a stack of conductive layers interleaved with isolating layers in a redistribution layer (RDL) structure of a semiconductor device; and
forming first contact structures and second contact structures in the RDL structure, wherein:
each of the first contact structures extends through a portion of the conductive layers and the isolating layers and is connected to a pad on a first interface of the RDL structure; and
each of the second contact structures is connected to a respective one of the first contact structures through one of the conductive layers, and each of the second contact structures is connected to a pad on a second interface of the RDL structure opposite to the first interface.

17. The method according to claim 16, further comprising:
forming a slit in the RDL structure to separate a pair of neighboring contact structures of the first contact structures and to separate a pair of neighboring contact structures of the second contact structures, wherein a contact structure of the first contact structures and a contact structure of the second contact structures are on a same side of the slit and are connected through one of the conductive layers.

18. The method according to claim 17, further comprising:
filling a first isolating material to the slit;
filling a second isolating material in each of the first contact structures to form an isolating layer on an inner surface of each of the first contact structures; and
filling a first conductive material in the first contact structures and a second conductive material in the second contact structures.

19. The method according to claim 18, further comprising:
after filling the second conductive material in the second contact structures, forming, in the second contact structures, a third isolating material over the second conductive material.

20. The method according to claim 16, wherein each of the first contact structures comprises a first trench, and each of the second contact structures comprises a second trench.
